(19) United States
(12) Patent Application Publication
(10) Pub. No.: US 2011/0108102 A1
(43) Pub. Date: May 12, 2011

(54) SOLAR CELL WITH ENHANCED EFFICIENCY

(75) Inventors: Marilyn Wang, Shanghai (CN); Linan Zhao, Shanghai (CN); Zhi Zheng, Shanghai (CN)

(73) Assignee: Honeywell International Inc., Morristown, NJ (US)

(21) Appl. No.: 12/614,054

(22) Filed: Nov. 6, 2009

(51) Int. Cl. H01L 51/46; H01L 31/00; H01L 51/48

(52) U.S. Cl. 136/256; 438/82; 136/263; 257/E51.012

(57) ABSTRACT

Solar cells and methods for manufacturing solar cells are disclosed. An example solar cell may include a substrate, which in some cases may act as an electrode, a nano-pillar array coupled relative to the substrate, a self-assembled monolayer disposed on the nano-pillar array, an active layer provided on the self-assembled monolayer, and an electrode electrically coupled to the active layer. In some cases, the self-assembled monolayer may include alkanedithiol, and the active layer may include a photoactive polymer, but this is not required.

### CROSS-REFERENCE TO RELATED APPLICATIONS

This application is related to U.S. patent application Ser. No. 12/468,755, filed May 19, 2009 and entitled “SOLAR CELL WITH ENHANCED EFFICIENCY”, and is also related to U.S. patent application Ser. No. 12/433,560, filed on Apr. 30, 2009 and entitled “AN ELECTRON COLLECTOR AND ITS APPLICATION IN PHOTOVOLTAICS”, the entire disclosures of which are incorporated herein by reference.

### TECHNICAL FIELD

The disclosure relates generally to solar cells. More particularly, the disclosure relates to solar cells with enhanced efficiency and methods for manufacturing the same.

### BACKGROUND

A wide variety of solar cells have been developed for converting light into electricity. Of the known solar cells, each has certain advantages and disadvantages. There is an ongoing need to provide alternative solar cells with enhanced efficiency, as well as methods for manufacturing solar cells.

### SUMMARY

The disclosure relates generally to solar cells with enhanced efficiency, and methods for manufacturing solar cells. An illustrative solar cell includes a substrate, with a nano-pillar array coupled to the substrate. A self-assembled monolayer is provided above the nano-pillar array, with an active layer provided above the self-assembled monolayer.

In some cases, the nano-pillar array may be a nano-tube or nano-wire array, which may include or may be made from TiO₂/ZnO or any other suitable material. The self-assembled monolayer may be or may include an alkanedithiol layer disposed on the nano-pillar layer. The active layer may be or may include P3HT/PCBM, and may be provided on the self-assembled monolayer. These are only example materials. An example method for manufacturing a solar cell may include providing a substrate, providing a nano-pillar array on the substrate, providing a self-assembled monolayer such as an alkanedithiol monolayer on the nano-pillar array, and then providing an active layer on the self-assembled monolayer. Anode and cathode electrodes for the solar cell may also be provided.

The above summary is not intended to describe each and every embodiment or feature of the disclosure. The Figures and Description which follow more particularly exemplify certain illustrative embodiments.

### BRIEF DESCRIPTION OF THE DRAWINGS

The invention may be more completely understood in consideration of the following detailed description of various embodiments of the invention in connection with the accompanying drawing, in which:

FIG. 1 is a schematic cross-sectional side view of an illustrative solar cell.

While the invention is amenable to various modifications and alternative forms, specifics thereof have been shown by way of example in the drawing and will be described in detail. It should be understood, however, that the intention is not to limit the invention to the particular embodiments described. On the contrary, the intention is to cover all modifications, equivalents, and alternatives falling within the spirit and scope of the invention.

### DESCRIPTION

For the following defined terms, these definitions shall be applied, unless a different definition is given in the claims or elsewhere in this specification.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the terms “about” may include numbers that are rounded to the nearest significant FIGURE.

The recitation of numerical ranges by endpoints includes all numbers within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

As used in this specification, the term “array” can include a set of elements that are in a regular, an irregular and/or a random or pseudorandom pattern. For example, a nano-tube or nano-wire array may include set of nano-tube or nano-wire elements that are arranged in a regular, an irregular and/or a random or pseudorandom pattern.

The following description should be read with reference to the drawing. The drawing, which is not necessarily to scale, depicts an illustrative embodiment and is not intended to limit the scope of the invention.

A wide variety of solar cells (which also may be known as photovoltaics and/or photovoltaic cells) have been developed for converting sunlight into electricity. Some example solar cells include a layer of crystalline silicon. Second and third generation solar cells often utilize a thin film of photovoltaic material (e.g., a “thin” film) deposited or otherwise provided on a substrate. These solar cells may be categorized according to the photovoltaic material deposited. For example, inorganic thin-film photovoltaics may include a thin film of amorphous silicon, microcrystalline silicon, CdS, CdTe, Cu₂S, copper indium diselenide (CIS), copper indium gallium diselenide (CIGS), etc. Organic thin-film photovoltaics may include a thin film of a polymer or polymers, bulk heterojunctions, ordered heterojunctions, a fullerence, a polymer/fullerence blend, photosynthetic materials, etc. These are only examples.

Efficiency may play an important role in the design and production of photovoltaics. One factor that may correlate to efficiency is the active layer thickness. A thicker active layer is typically able to absorb more light. This may desirably improve efficiency of the cell. However, thicker active layers often lose more charges due to higher internal resistance and/or increased recombination, which reduces efficiency. Thinner active layers may have less internal resistance and/or less recombination, but typically do not absorb light as effectively as thicker active layers.

The solar cells disclosed herein are designed to be more efficient by, for example, increasing the light absorbing ability of the active layer while reducing internal resistance and/or recombination. The methods for manufacturing photovoltaics and/or photovoltaic cells disclosed herein are aimed at producing more efficient photovoltaics at a lower cost.

At least some of the solar cells disclosed herein utilize an active layer that includes a polymer or polymers. For example, as least some of the solar cells disclosed herein include an active layer that includes a bulk heterojunction (BHJ) using conductive polymers. Solar cells that include a BHJ based on conductive polymers may be desirable for a number of reasons. For example, the costs of manufacturing a BHJ based on conductive polymers may be lower than the costs of manufacturing active layers of other types of solar cells. This may be due to the lower cost associated with the materials used to make such a BHJ (e.g., polymers) solar cell, as well as possible use of roll-to-roll and/or other efficient manufacturing techniques.

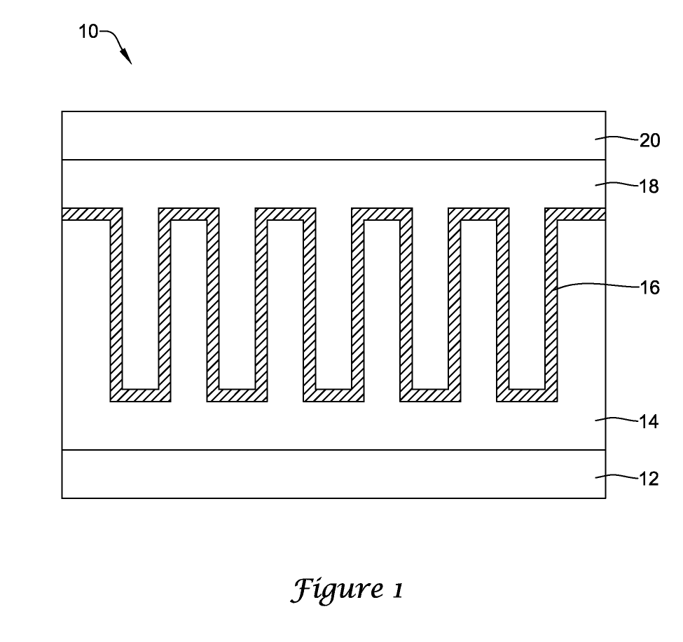

FIG. 1 is a schematic cross-sectional side view of an illustrative solar cell 10. In the illustrative embodiment, solar cell 10 includes a substrate 12. Substrate 12 may include or otherwise take the form of a first electrode (e.g., a cathode or positive electrode). A layer 14 of material may be electrically coupled to or otherwise disposed on substrate 12. In the illustrative embodiment, the layer 14 of material may be formed from a material that is suitable for accepting excitons from an active layer 18 of the solar cell 10. The layer 14 of material may include or be formed as a structured pattern or array, such as a nano-pillar (e.g., nano-wire, nano-tube, etc.) array 14. While the nano-pillar array of FIG. 1 is shown as a regular pattern of nano-pillar elements, it is contemplated that the nano-pillar array may be arranged as a regular, an irregular and/or a random or pseudorandom pattern, as desired.

As shown in FIG. 1, a layer 16 may be disposed on or above the nano-pillar array 14. Layer 16 is shown as generally tracing the pattern of nano-pillar array 14, but this is not required. An active layer 18 is shown coupled to or otherwise disposed over the structured pattern or array in layers 14/16, if desired. As such, the active layer 18 “fills in” the structured pattern or array in layers 14/16, thereby at least partially planarizing the device. Solar cell 10 may also include a second electrode 20 (e.g., an anode or negative electrode) that is electrically coupled to active layer 18. In some embodiments, the polarity of the electrodes may be reversed. For example, substrate and/or first electrode 12 may be an anode and second electrode 20 may be a cathode. Consequently, first electrode 12 may accept electrons from active layer 18 and second electrode 20 may receive holes from active layer 18.

Substrate 12, when provided, may be made from any number of different materials including polymers, glass, and/or transparent materials. In one example, substrate 12 may include polyethylene terephthalate, polyimide, low-iron glass, or any other suitable material, or combination of suitable materials. In another example (e.g., where substrate 12 includes the first electrode), substrate 12 may include, fluorine-doped tin oxide, indium tin oxide, Al-doped zinc oxide, any other suitable conductive inorganic element or compound, conductive polymer, and other electrically conductive material, or any other suitable material as desired. In some embodiments, solar cell 10 may lack substrate 12 and, instead, may rely on another structure to form a base layer, if desired.

In some instances, layer 14 may include an electron conductor. In some cases, the electron conductor may be an n-type electron conductor, but this is not required. The electron conductor may be metallic and/or semiconducting, such as TiO₂ and/or ZnO. In some cases, the electron conductor may be an electrically conducting polymer such as a polymer that has been doped to be electrically conducting and/or to improve its electrical conductivity. In some instances, the electron conductor may be formed of titanium dioxide that has been sinterized. As further described below, layer 14 may take the form of a nano-pillar array, if desired.

Active layer 18 may include a variety of different materials. In some embodiments, active layer 18 may include one or more materials or layers. In one example, active layer 18 may include an interpenetrating network of electron donor and electron acceptor materials or layers. In another illustrative embodiment, active layer 18 may include one or more polymers or polymer layers. In one example, active layer 18 may include an interpenetrating network of electron donor and electron acceptor polymers.

In at least some embodiments, active layer 18 may include an interpenetrating network of poly-3-hexylthiophen (P3HT) and [6,6]-phenyl-C61-butyric acid methyl ester (PCBM). It is contemplated that other materials may be used, as desired. P3HT is a photoactive polymer. Consequently, the P3HT material may absorb light and generate electron-hole pairs (excitons). While not being bound by theory, it is believed that as light is absorbed by active layer 18, an exciton is generated that diffuses to a nearby P3HT/PCBM interface within the active layer 18. The electrons may then be injected into the PCBM, which may have an energy band gap relative to P3HT so as to readily accept electrons from the P3HT material. The electrons may then be transported along the PCBM chain to the second electrode 20. The holes may be transported within the P3HT to a nearby pillar of, for example, a nano-pillar array in layer 14 and ultimately to the first electrode 12. As indicated above, layer 14 may have an energy band gap relative to the active layer 18 that is suitable for accepting excitons (e.g. holes) from the active layer 18.

Other materials are contemplated for active layer 18. For example, active layer 18 may include low band gap polymers, small molecule materials, organic small molecules, etc. In some embodiments, active layer 18 may include one or more of:

copper phtalocyanine/fullerene C₆₀ (CuPc/C₆₀),

poly[9,9-didecanefluorene-alt-(bis-thienylene) benzothiadiazole],

APFO-Green 5,

poly[N-9-heptadecanyl-2,7-carbazole-alt-5,5-(4′,7′di-2-thienyl-2′,1′,3′-benzothiadiazole)],

poly[2,6-(4,4-bis-(2-ethylhexyl)-4H-cyclopenta[2,1-b; 3,4-b2]-dithiophene)-alt-4,7-(2,1,3-benzothiadiazole)],

poly{5,7-di-2-thienyl-2,3-bis(3,5-di(2-ethylhexyloxy)phenyl)thieno[3,4-b]pyrazine}, platinum (II) polyyne polymer,

PCBM,

P3HT, and

PIF-DTP having the structure of:

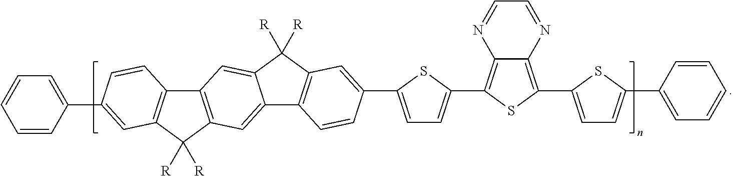

The thickness of the active layer can have a significant effect on the efficiency of a solar cell. The pattern in layer 14, when provided, may decrease the effective thickness of the active layer 18, which may increase the efficiency of the solar cell. As indicated above, and while not limited to such, the pattern in layer 14 may be a nano-pillar array that includes a plurality of nano-pillars or projections that extend upward, as shown in FIG. 1. In an illustrative embodiment, the nano-pillars may have a width on the order of about 40-60 nm, or about 50 nm, and a spacing on the order of 10-80 nm, or about 25 nm. In some embodiments, the nano-pillar elements may have a substantially squared shape as shown so that the width is uniform in perpendicular directions. In other embodiments, the nano-pillar elements may be cylindrical in shape and, thus, may have a uniform width in all directions. However, it is contemplated that the nano-pillar elements may have any suitable shape including honeycomb shaped, star shaped, or any other shape, as desired. The nano-pillar elements may be arranged so that adjacent nano-pillars are spaced so as to form wells or channels therebetween. In some cases, the height of the nano-pillars relative to their width may result in a relatively large aspect ratio, but this is not required. For example, the height of the nano-pillar elements may be about 200-400 nm, or about 250 nm, which may result in about a 5:1 aspect ratio or more. It is contemplated that active layer 18 may be provided in the wells or channels between the nano-pillars, as shown. That is, the active layer 18 may “fill in” the forest of nano-pillar elements. In some cases, the active layer 18 may be spin coated on the nano-pillars to help fill in the wells and channels.

In general, the distance between adjacent nano-pillars may be configured so as to improve the efficiency of the solar cell 10. For example, the distance between adjacent nano-pillars may be set to about 10-80 nm or less, or set to about 25 nm or less. For example, with a pattern of square nano-pillars spaced at 25 nm, the furthest distance an exciton must travel within the active layer to an adjacent nano-pillar is about 35 nm. This travel distance can define the worst case “effective” thickness of the active layer 18. Note, in this illustrative embodiment, many of the excitons (e.g. holes) may travel laterally though the active layer to an adjacent nano-pillar, rather than vertically down to layer 14. In comparison, typical solar cells that utilize a BHJ may have a planar active layer with a thickness of about 100-200 nm. When so provided, the worst case “effective” thickness of such an active layer may be 100-200 nm. As can be seen, the effective thickness of the active layer 18 in solar cell 10 may be considerably reduced, which may help increase the efficiency of solar cells 10 by reducing internal resistance and/or recombination within the active layer 18.

It is also noted that a pattern in layer 14 may produce light scattering within the active layer 18 in solar cell 10. Because of this light scattering, more light (photons) may be absorbed by active layer 18. To help increase the light scatter and corresponding absorption of light in the active layer 18, it is contemplated that the height of the pattern in layer 14 relative to the width of the patterned elements may produce a relatively large aspect ratio (e.g. 2:1, 5:1, 10:1 or more). As mentioned above, the aspect ratio of the nano-pillars may be about 5:1, but this is only an example.

While nano-pillars are shown in FIG. 1 for layer 14, this is not required. In some instances, layer 14 may be planar. However, when layer 14 is non-planar, it is contemplated that other arrangements or patterns may be used beyond the nano-pillars shown in FIG. 1. In general, the structural arrangement of a pattern in layer 14, when provided, may be configured to produce a reduced effective thickness of the active layer 18 relative to a simple planar surface, and may include one or more projections and/or impressions, be textured, have surface features and/or other irregularities, or have other non-planar features, as desired.

In some cases, disposing active layer 18 on layer 14 may result in a frequency shift in the absorption spectrum of the active layer 18. For example, disposing a P3HT/PCBM active layer 18 on a TiO₂/ZnO nano-pillar array layer 14 may result in a blue-shifted absorption spectrum of the active layer 18. Because of this, the efficiency of solar cell 10 may be somewhat decreased. Additionally, if active layer 18 is disordered, the overlap with the solar spectrum, the exciton diffusion, and the carrier transport may be reduced, thereby reducing the efficiency of solar cell 10.

To help enhance the efficiency solar cell 10, layer 16 may be disposed between layer 14 and active layer 18. In at least some embodiments, layer 16 may modify or otherwise form a self-assembled monolayer on layer 14. As such, and in some cases, layer 16 may reduce the frequency shift (e.g. blue shift) in the absorption spectrum of the active layer 18, and may help enhance the overall efficiency of solar cell 10.

Layer 16 may include one or more suitable materials. In at least some embodiments, layer 16 may include alkanedithiols. For example, layer 16 may include octadecanethiol, which may reduce the blue shift in the absorption spectrum discussed above by up to about 90%. Other alkanedithiols may be utilized and/or mixtures of alkandithiols. Some alkanedithiols may be desirable because, for example, they do not react with active layer 18 and they readily form monolayers on layer 14 (e.g., ZnO surfaces through Zn—S bonding). In addition, adding different alkanedithiols to active layer 18 to “modify” active layer 18 may help reduce or minimize other unwanted absorption shifts, which can enhance the efficiency of solar cell 10.

An example method for manufacturing solar cell 10 may include providing the layer 14 on or above the substrate 12. As discussed above, the layer 14 may include a nano-pillar array (e.g., nano-wires, nano-tubes, etc.). When so provided, the a nano-pillar array may be grown or otherwise provided on the substrate 12, such as by electrochemical process, a physical process, a chemical process, imprinting, etc.

Layer 16 may be formed on or above nano-pillar array 14. In some cases, layer 16 may be provided by soaking nano-pillar array 14 in a solution of alkanedithiols in ethanol. For example, nano-pillar array 14 may be soaked in a 1 mM solution of alkanedithiols for about 72 hours or so. After soaking, the alkanedithiol-coated nano-pillar array may be removed from the solution, rinsed (e.g., with ethanol), and dried (e.g., with flowing nitrogen).

Active layer 18 may be disposed on layer 16 using any suitable method. In one example, the materials for active layer 18 (e.g., P3HT/PCBM) may be mixed in a suitable solvent (e.g., chloroform) and spin-coated onto patterned layers 14/16. The spin-coating process may help distribute the active layer 18 throughout the pattern (when provided) on layers 14/16, e.g. filling the spaces between nano-pillars. The resultant active layer 18 may be about 80 nm thick, for example. Active layer 18 may by annealed at about 150° C. in a nitrogen atmosphere and allowed to cool to room temperature over about 45 minutes. The second electrode 20, which may be aluminum or any other suitable material, may be provided over active layer 18 using any suitable method such as e-beam evaporation or sputtering. Second electrode 20 may be about 100 nm thick or so, or any other suitable thickness. Such a method may be easily scaled-up, which may make manufacturing of solar cells like solar cell 10 more cost-effective for a variety of applications including applications that use large quantities or sheets of solar cells 10.

It should be understood that this disclosure is, in many respects, only illustrative. Changes may be made in details, particularly in matters of shape, size, and arrangement of steps without exceeding the scope of the invention. The invention's scope, of course, is defined in the language in which the appended claims are expressed.

What is claimed is:

1. A solar cell, comprising:
a substrate;
a nano-pillar array coupled to the substrate;
a self-assembled monolayer disposed on the nano-pillar array; and
an active layer disposed on the self-assembled monolayer.

2. The solar cell of claim 1, wherein the substrate includes glass.

3. The solar cell of claim 1, wherein the substrate includes polyethylene terephthalate.

4. The solar cell of claim 1, wherein the nano-pillar array includes TiO₂.

5. The solar cell of claim 1, wherein the nano-pillar array includes ZnO.

6. The solar cell of claim 1, wherein the self-assembled monolayer includes an alkanedithiol layer.

7. The solar cell of claim 6, wherein the self-assembled monolayer includes an octadecanethiol.

8. The solar cell of claim 1, wherein the active layer includes an organic small molecule.

9. The solar cell of claim 1, wherein the active layer includes a polymer.

10. The solar cell of claim 1, wherein the active layer includes an interpenetrating network electron donors and electron acceptors.

11. The solar cell of claim 1, wherein the active layer includes an interpenetrating network of poly-3-hexylthiophen and [6,6]-phenyl-C61-butyric acid methyl ester.

12. A solar cell, comprising:
a first layer;
an alkanedithiol layer disposed on the first layer; and
an active layer disposed on alkanedithiol layer.

13. The solar cell of claim 12, wherein the first layer is a TiO₂/ZnO layer arranged in a nano-pillar array.

14. The solar cell of claim 13, wherein the nano-pillar layer is grown on a substrate.

15. The solar cell of claim 12, wherein the alkanedithiol layer includes an octadecanethiol.

16. The solar cell of claim 12, wherein the active layer includes a polymer.

17. The solar cell of claim 16, wherein the active layer includes an interpenetrating network of poly-3-hexylthiophen and [6,6]-phenyl-C61-butyric acid methyl ester.

18. A method for manufacturing a solar cell, comprising:
providing a substrate;
providing a nano-pillar array above the substrate;
providing an alkanedithiol monolayer on the nano-pillar array; and
providing an active layer on the alkanedithiol monolayer.

19. The method of claim 18, wherein the nano-pillar array includes a material selected from the group comprising TiO₂ and ZnO.

20. The method of claim 16, wherein the wherein the alkanedithiol monolayer includes an octadecanethiol.
